(19) United States
(12) Patent Application Publication
(10) Pub. No.: US 2016/0081224 A1
(43) Pub. Date: Mar. 17, 2016

(54) ARRANGEMENT AND METHOD FOR COOLING LIQUID-COOLED ELECTRONICS

(71) Applicant: Adwatec Oy, Kangasala (FI)

(72) Inventors: Jorma TERÄVÄ, Tampere (FI); Arto VERRONEN, Tampere (FI)

(73) Assignee: ADWATEC OY, Kangasala (FI)

(21) Appl. No.: 14/852,760

(22) Filed: Sep. 14, 2015

(30) Foreign Application Priority Data
Sep. 15, 2014 (DE) 102014013653.1

(51) Int. Cl. H05K 7/20

(52) U.S. Cl. CPC H05K 7/20381; H05K 7/20327

(57) ABSTRACT

An arrangement and a method are provided for cooling liquid-cooled electronics. The arrangement includes a pipe system, said pipe system including receiving and exit coolant flow pipes for connecting the arrangement to a liquid-cooling system of said liquid-cooled electronics, inlet and outlet coolant flow pipes for connecting the arrangement to a heat exchanger arrangement, and an expansion tank connected to the coolant flow pipes. The arrangement further includes a coolant level transmitter arranged to detect the amount of the coolant in the expansion tank, a temperature measure arrangement arranged for measuring temperature of the coolant in the arrangement, and a leakage control system. The leakage control system includes a calculator for calculating a temperature corrected reference value for the amount of the coolant in the expansion tank and for calculating a temperature corrected coolant volume by using said temperature corrected reference value.

### BACKGROUND

The invention relates to an arrangement for cooling liquid-cooled electronics.

The invention further relates to a method for cooling liquid-cooled electronics.

Cooling arrangements and systems for cooling SVC (Static VAR Compensator) systems etc. by circulating liquid coolant are commonly known. In these arrangements the heat energy is transferred from the coolant into air or another liquid by a heat exchanger.

Said cooling arrangements are usually complicated and comprise lot of joints and gaskets. Therefore, there is a potential risk for leakage in said cooling arrangements.

A problem with this is that the leakage is usually difficult to notice prior to a significant amount of the coolant is lost and/or the leaking component is badly damaged. At that point the repairing of the component may hamper the use of the system to be cooled or even necessitate running down the system.

### BRIEF DESCRIPTION

Viewed from a first aspect, there can be provided an arrangement for cooling liquid-cooled electronics, the arrangement comprising a pipe system, said pipe system comprising receiving and exit coolant flow pipes for connecting the arrangement to a liquid-cooling system of said liquid-cooled electronics, inlet and outlet coolant flow pipes for connecting the arrangement to a heat exchanger arrangement, and an expansion tank connected to the coolant flow pipes, the arrangement further comprising a coolant level transmitter arranged to detect the amount of the coolant in the expansion tank, a temperature measure arrangement arranged for measuring temperature of the coolant in the arrangement, and a leakage control system, comprising a calculation means for calculating a temperature corrected reference value for the amount of the coolant in the expansion tank and for calculating a temperature corrected coolant volume by using said temperature corrected reference value.

Viewed from a further aspect, there can be provided a method for cooling liquid-cooled electronics, the method comprising: receiving coolant flow from the liquid-cooling system of said liquid-cooled electronics in a pipe system, feeding coolant flow to a heat exchanger arrangement, receiving cooled coolant flow from the heat exchanger arrangement to the pipe system, and feeding cooled coolant flow back from the pipe system to the liquid-cooling system of said liquid-cooled electronics, wherein said pipe system further comprises an expansion tank containing said coolant, whereby the method further comprises: detecting the amount of the coolant in the expansion tank, measuring temperature of the coolant in the arrangement, and compensating result by calculating of coolant thermal expansion in the arrangement based on said temperature measurement.

The arrangement and the method are characterised by what is stated in the characterising parts of the independent claims. Some other embodiments are characterised by what is stated in the other claims. Inventive embodiments are also disclosed in the specification and drawings of this patent application. The inventive content of the patent application may also be defined in other ways than defined in the following claims. The inventive content may also be formed of several separate inventions, especially if the invention is examined in the light of expressed or implicit sub-tasks or in view of obtained benefits or benefit groups. Some of the definitions contained in the following claims may then be unnecessary in view of the separate inventive ideas. Features of the different embodiments of the invention may, within the scope of the basic inventive idea, be applied to other embodiments.

### BRIEF DESCRIPTION OF FIGURES

Some embodiments illustrating the present disclosure are described in more detail in the attached drawings, in which

FIG. 1 is a schematic flow chart of an example arrangement, and

FIG. 2 is a schematic perspective view of an example arrangement.

In the figures, some embodiments are shown simplified for the sake of clarity. Similar parts are marked with the same reference numbers in the figures.

### DETAILED DESCRIPTION

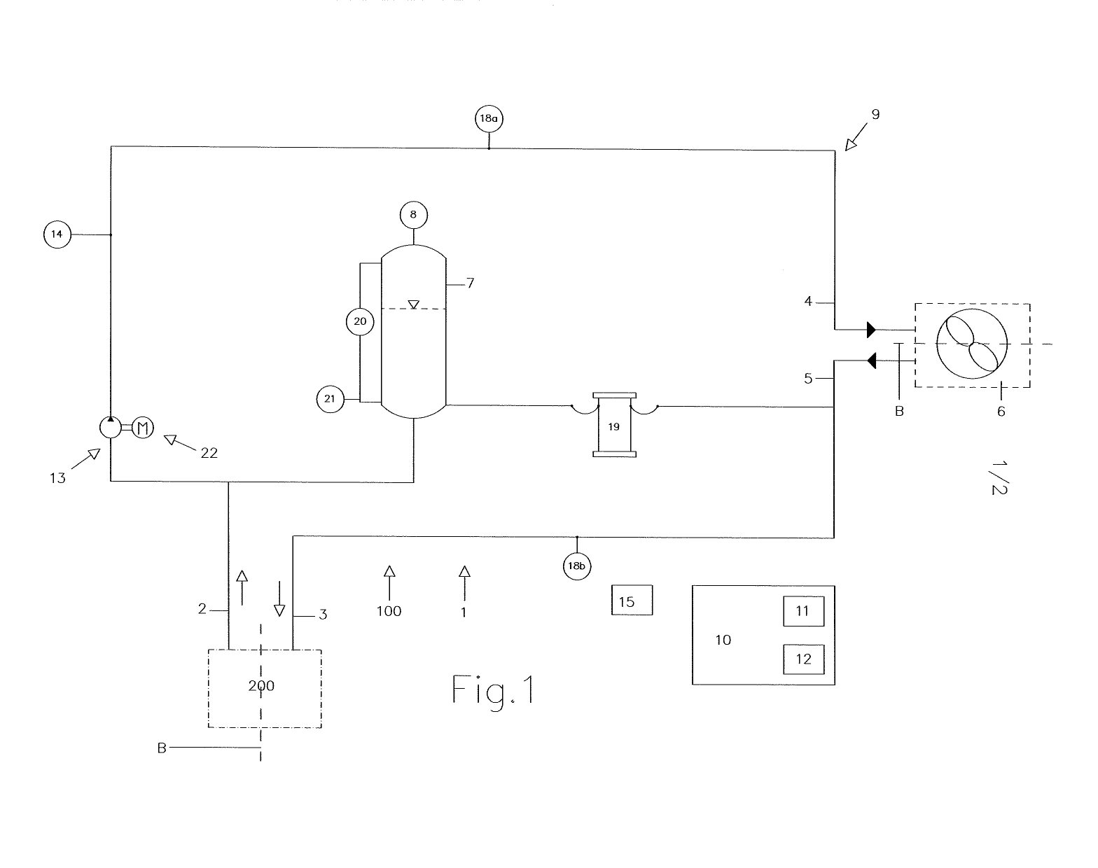

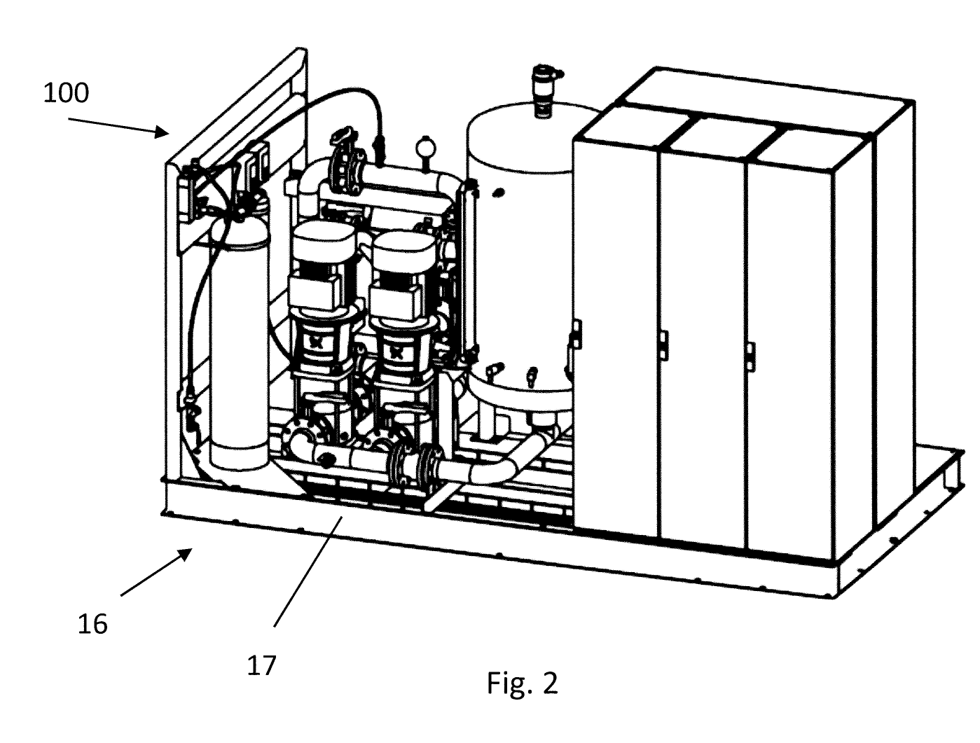

FIG. 1 is a schematic flow chart of an example arrangement, and FIG. 2 is a schematic perspective view of an example arrangement. The arrangement 100 shown is connected to a liquid-cooling system of a liquid-cooled electronics 200 for cooling said electronics 200. The liquid-cooled electronics 200 may be e.g. a SVC (Static VAR Compensator) unit, or a HVDC/HVAC (High Voltage DC/High Voltage AC) unit, or an AC Drive, an electrical motor, a transformer, a generator, a converter or other liquid-cooled power electric system.

The arrangement 100 circulates coolant between the liquid-cooled electronics 200 and a heat exchanger arrangement 6. For this purpose the arrangement 100 includes a pipe system 1, which comprises receiving 2 and exit 3 coolant flow pipes, and feeding 4 and return 5 coolant flow pipes.

The receiving 2 and exit 3 coolant flow pipes are connected to the liquid-cooling system of the liquid-cooled electronics 200, whereas feeding 4 and return 5 coolant flow pipes are connected to the heat exchanger arrangement 6. Thus there is established a pressurized closed loop cooling circuit comprising the liquid-cooling system of the liquid-cooled electronics 200, the arrangement 100 and the heat exchanger arrangement 6.

The coolant may be e.g. water, de-ionized water or water-alcohol mixture, such as water-glycol or water-ethanol mixture, salt water, liquid salt, oil or other heat transfer fluid.

The heat exchanger arrangement 6 may comprise one or more heat exchangers, where the excessive heat energy of the coolant is transferred to liquid or air, and cooled coolant is returned by the return 5 coolant flow pipes in the arrangement 100. In an embodiment of the invention, the heat exchanger arrangement 6 is included in the arrangement 100, but, however, this is not necessary.

The arrangement may comprise at least one pump 13 for running the coolant in the arrangement 100. The type and operating principle of the pump are known per se.

There are typically significant temperature variations of coolant in the arrangement 100 due to changing heat load in the liquid-cooled electronics 200. Therefore the arrangement 100 comprises an expansion tank 7 that is connected to the coolant flow pipes. The capacity of the expansion tank 7 depends e.g. on ambient temperature range, coolant temperature range and the volume of the coolant circulating in the arrangement 100, in the heat exchanger arrangement and in the liquid-cooling system of a liquid-cooled electronics 200. In an embodiment of the invention, said capacity is 400 litres. The expansion tank 7 may be pressurized over atmospheric pressure.

A temperature measure arrangement 9 is arranged to measure temperature of the coolant in the arrangement 100. The temperature measure arrangement 9 comprises at least one temperature transmitter. The arrangement shown in FIG. 1 comprises two temperature transmitters 18a, 18b, the first 18a of which being arranged to measure the temperature of the hot coolant flowing towards the heat exchanger arrangement 6, whereas the second temperature transmitter 18b is arranged to measure the temperature of the cooled coolant flowing towards the liquid-cooling system of the liquid-cooled electronics 200. The type and operating principle of the temperature transmitters are known per se.

The arrangement 100 further comprises at least one coolant level transmitter 8 that is arranged to detect the amount of the coolant in the expansion tank 7. The amount of the coolant in the expansion tank 7 indicates the coolant volume change in the cooling system and it may vary due to e.g. leakage or change of temperature.

According to an embodiment of the invention, the coolant level transmitter 8 is an acoustical sensor, especially an ultrasonic sensor. Alternatively, the coolant level transmitter 8 comprises a mechanical float, a laser or light measuring device, a photoelectric sensor, a conductivity meter, a resistivity meter, an inductive or capacitive meter, a magnetic meter or a weight measuring means arranged to weight the expansion tank 7.

In order to detect possible leakages, the arrangement 100 includes a leakage control system 10. This comprises a calculation means 11 and, in certain embodiments, an alarm means 12.

The calculation means 11 may comprise any known calculation unit, e.g. microprocessor, integrated circuit, programmable logic control etc.

The calculation means 11 is arranged, i.e. programmed to calculate a temperature corrected reference value V(REF) for the amount of the coolant in the expansion tank 7 e.g. according to the following:

V(REF)=V(MEAS)+((TT1−TT(REF))×V1+(TT2−TT(REF))×V2)×C1

wherein
V(REF)=Temperature corrected coolant volume in the expansion tank 7,
V(MEAS)=Measured coolant volume in the expansion tank 7,
TT1=Current coolant temperature measured by the first temperature transmitter 18a,
TT(REF)=Reference temperature,
V1=Cooling system volume of the hot side of the cooling system,
TT2=Current coolant temperature measured by the second temperature transmitter 18b,
V2=Cooling system volume in the cool side of the system, including the volume of the coolant purification apparatus and the volume of the expansion tank 7,
C1=Volumetric thermal expansion coefficient of the coolant.

It should be underlined, that the equation above is just an example of the equations that may be used. For example, if the arrangement comprises one temperature transmitter only, the temperature is measured by said temperature transmitter only.

Boundaries B between the hot side and the cool side of the cooling system may be arranged in suitable points in the heat exchanger arrangement 6 and the liquid-cooled electronics 200. According to an idea, said suitable points are situated in the middle of the volume of the cooling system included in the heat exchanger arrangement 6 and, respectively, in the liquid-cooled electronics 200.

There is a certain frequency in calculating or measuring the temperature corrected reference value V(REF). Based on these consecutive calculations or measurements the leakage control system 10 is able to observe if the volume of the coolant is changing. The use of temperature corrected reference value V(REF) instead of direct use of the coolant level in the expansion tank 7 makes it possible to distinguish coolant level variations being consequences of coolant expansion and contraction with temperature variations from those taking place due to leakages of the coolant system.

The function of the alarm means 12 is arranged to depend on the temperature corrected reference value V(REF) for the amount of the coolant. The alarm means 12 may be programmed to various alarms depending on the rate of the leaking. For example, a major leak alarm will be given if the temperature corrected reference volume of the coolant changes over certain given value in a short period of time, like in 20 seconds, whereas a minor leak alarm will be given if the temperature corrected reference volume of the coolant changes over certain given value in a long period of time, like in one week. It is to be noted, however, that these alarms are just an example of alarms that can be used in the arrangement 100, e.g. there may be just one alarm, or more than two alarms depending on the need of the arrangement 100 and/or the liquid-cooled electronics 200.

The arrangement 100 may, additionally, comprise one or more coolant level indicator(s) 20 and coolant lever switch(s) 21. These components are arranged to be back-up indicators for current or true amount of coolant.

As disclosed earlier, the arrangement 100 may comprise a purification apparatus 19, e.g. an ion exchanger, which is arranged for purification of the coolant. The purification apparatus 19 may be connected to the pipe system 1 to purify a partial coolant flow flowing from the heat exchanger arrangement 6 to the expansion tank 7 as shown in FIG. 1. There are also other alternatives to connect the purification apparatus 19 to the pipe system 1. The purification apparatus 19 may be e.g. a mixed bed ion exchanger, a filter, a reverse osmosis unit or any other purification apparatus known per se.

The arrangement 100 shown in the Figures further comprises a pump 13 and a motor 22 operating said pump. The pump 13 is arranged to run the coolant in the arrangement 100 and, optionally, in the liquid-cooled electronics 200. The pump 13 and the motor 22 may be any suitable pump and motor know per se.

There may also be a pressure transmitter 14 arranged for measuring pressure of the coolant in the pipe system 1. The pressure transmitter 14 can not only be used for detecting the pressure of the pipe system 1, but it can also be utilized with means 15 for detecting the residual gas content of the coolant in the pipe system 1. Said means 15 may comprise any known calculation unit, e.g. microprocessor, integrated circuit, programmable logic control etc. In an embodiment of the invention, the means 15 are integrated with the calculation means 11 described above.

The means 15 for detecting the residual gas content of the coolant is fed by pressure information from the pressure transmitter 14. The compression property of the coolant varies depending on the gas content of the coolant. The aim or optimum is that there is no gas in the coolant at all. If the coolant comprises gas, it may compress slightly when the pump 13 is started. The compression of the coolant can be detected by the pressure transmitter 14. The residual gas content is then calculated based on temperature corrected coolant volume in the expansion tank 7 and pressure values when the pump 13 is running and stopped. According to an idea, the residual gas content V(GAS) is calculated as follows:

V(GAS)=(P1/(P1−P2))×(V(REF, STOP)−V(REF, RUN))−C

wherein
V(GAS)=Estimation of the residual gas volume in the pipe system at expansion tank pressure,
P1=(Pump pressure−expansion tank pressure)/2=average pressure rise in the pipe system 1 when the pump 13 is running,
P2=absolute pressure in the expansion tank 7,
V(REF,STOP)=Temperature corrected coolant volume in the expansion tank 7 when the pump 13 is stopped,
V(REF,RUN)=Temperature corrected coolant volume in the expansion tank 7 when the pump 13 is running,
C=elasticity constant of the pipe system. Usually C is zero, i.e. the elasticity of the pipe system 1 may be ignored as the pressure rise is typically reasonable low.

The means 15 for detecting the residual gas content of the coolant is especially useful in the start-up stage of the arrangement 100, because the means 15 opens up a possibility to detect the moment the pipe system 1 is completely degassed.

It is to be noted here, that at least critical components of the arrangement 100 may be duplicated for giving high reliability.

As can be seen in FIG. 2, the arrangement 100 may be an independent module 16 comprising a frame structure 17 in which the pipe system 1 and the expansion tank 7 as well as other components of the arrangement 100 are attached. The module 16 can be easily transported and handled during its installing.

The arrangement may be used to put into practice the following method:
a) receiving coolant flow from the liquid-cooling system of a liquid-cooled electronics 200 in a pipe system 1,
b) feeding a coolant flow to a heat exchanger arrangement 6,
c) receiving a cooled coolant flow from the heat exchanger arrangement 6 to the pipe system 1, and
d) feeding cooled coolant flow back from the pipe system 1 to the liquid-cooling system of said liquid-cooled electronics 200, wherein said pipe system 1 further comprises an expansion tank 7 containing said coolant, whereby the method further comprises:
e) detecting the amount of the coolant in the expansion tank 7,
f) measuring temperature of the coolant in the arrangement (100), and
g) compensating result by calculating of coolant thermal expansion in the arrangement based on said temperature measurement.

The invention is not limited solely to the embodiments described above, but instead many variations are possible within the scope of the inventive concept defined by the claims below. Within the scope of the inventive concept the attributes of different embodiments and applications can be used in conjunction with or replace the attributes of another embodiment or application.

The drawings and the related description are only intended to illustrate the idea of the invention. The invention may vary in detail within the scope of the inventive idea defined in the following claims.

### REFERENCE SYMBOLS

1 pipe system
2 receiving coolant flow pipe
3 exit coolant flow pipe
4 inlet coolant flow pipe
5 outlet coolant flow pipe
6 heat exchanger arrangement
7 expansion tank
8 coolant level transmitter
9 temperature measure arrangement
10 leakage control system
11 calculation means
12 alarm means
13 pump
14 pressure transmitter
15 means for detecting residual gas content
16 module
17 frame structure
18a, 18b temperature transmitter
19 coolant purification apparatus
20 coolant level indicator
21 coolant lever switch
22 motor
100 arrangement
200 liquid-cooled electronics
B Boundary between hot and cool side

1-14. (canceled)

15. An arrangement for cooling liquid-cooled electronics, the arrangement comprising:
a pipe system, said pipe system comprising:
receiving and exit coolant flow pipes for connecting the arrangement to a liquid-cooling system of said liquid-cooled electronics;
inlet and outlet coolant flow pipes for connecting the arrangement to a heat exchanger arrangement; and
an expansion tank connected to the coolant flow pipes;
a coolant level transmitter arranged to detect the amount of the coolant in the expansion tank;
a temperature measure arrangement arranged for measuring temperature of the coolant in the arrangement; and
a leakage control system, the leakage control system comprising a calculator for calculating a temperature corrected reference value for the amount of the coolant in the expansion tank and for calculating a temperature corrected coolant volume by using said temperature corrected reference value.

16. The arrangement as claimed in claim 15, the arrangement being a cooling station of a SVC (Static VAR Compensator) unit, a HVDC/HVAC (High Voltage DC/High Voltage AC) unit, an AC Drive, an electrical motor, a transformer, a generator, and/or a converter.

17. The arrangement as claimed in claim 15, comprising a pump for running the coolant in the arrangement.

18. The arrangement as claimed in claim 15, further comprising a pressure transmitter arranged for measuring pressure of the coolant in the pipe system.

19. The arrangement as claimed in claim 15, further comprising:
a pump for running the coolant in the arrangement;
a pressure transmitter arranged for measuring pressure of the coolant in the pipe system; and
a detector for detecting the compression property of the coolant in the pipe system on the basis of the pressure of the coolant and the operation of the pump.

20. The arrangement as claimed in claim 15, wherein the coolant is water, de-ionized water or water-glycol mixture.

21. The arrangement as claimed in claim 15, wherein the arrangement is an independent module comprising a frame structure in which the pipe system and the expansion tank are attached.

22. The arrangement as claimed in claim 15, wherein the coolant level transmitter is an acoustical sensor.

23. The arrangement as claimed in claim 22, wherein the acoustical sensor is an ultrasonic sensor, a mechanical float, a laser or light measuring device, a photoelectric sensor, a conductivity meter, a resistivity meter, an inductive or capacitive meter, a magnetic meter, and/or a weight measuring device arranged to weigh the expansion tank.

24. The arrangement as claimed in claim 15, wherein the temperature measure arrangement comprises at least two temperature transmitters, comprising:
a first temperature transmitter arranged to measure the temperature of the hot coolant flowing towards the heat exchanger arrangement; and
another temperature transmitter arranged to measure the temperature of the cooled coolant flowing away from the heat exchanger arrangement.

25. The arrangement as claimed in claim 15, further comprising an alarm arranged to induce an alarm if temperature corrected coolant volume value fulfils conditions set for the alarm.

26. The arrangement as claimed in claim 15, further comprising a detector for detecting the residual gas content of the coolant in the pipe system.

27. A method for cooling liquid-cooled electronics, the method comprising the steps of:
receiving coolant flow from the liquid-cooling system of said liquid-cooled electronics in a pipe system;
feeding coolant flow to a heat exchanger arrangement;
receiving cooled coolant flow from the heat exchanger arrangement to the pipe system; and
feeding cooled coolant flow back from the pipe system to the liquid-cooling system of said liquid-cooled electronics,
wherein said pipe system further comprises an expansion tank containing said coolant, whereby the method further comprises the steps of:
detecting the amount of the coolant in the expansion tank;
measuring a temperature of the coolant in the arrangement; and
compensating a result by calculating coolant thermal expansion in the arrangement based on said temperature measurement.

28. The method as claimed in claim 27, further comprising the step of inducing an alarm if the temperature corrected reference value fulfils conditions set for the alarm.

29. The method as claimed in claim 27, further comprising the steps of:
running the coolant with a pump;
comparing the temperature corrected coolant volume when the pump is running and when the pump is stopped; and
calculating a residual gas content in the pipe system by comparing the temperature corrected coolant volumes and pressure values when the pump is running and stopped.
